(19) United States
(12) Patent Application Publication
(10) Pub. No.: US 2005/0221004 A1
(43) Pub. Date: Oct. 6, 2005

(54) Vapor reactant source system with choked-flow elements

(76) Inventors: Olli V. Kilpela, Helsinki (FI); Juhana Kostamo, Espoo (FI)

Correspondence Address: KNOBBE MARTENS OLSON & BEAR LLP, 2040 MAIN STREET, FOURTEENTH FLOOR, IRVINE, CA, 92614, US

(21) Appl. No.: 11/039,364

(22) Filed: Jan. 19, 2005

Related U.S. Application Data
(60) Provisional application No. 60/538,019, filed on Jan. 20, 2004.

(51) Int. Cl. C23C 16/00

(52) U.S. Cl. 427/248.1; 118/715

(57) ABSTRACT

A source system for introducing gaseous source chemicals to a reaction space is provided. The source system comprises an inactive gas source, a pressure controller, a reactant supply source, a gas flow control valve and a choked-flow element.

### REFERENCE TO RELATED APPLICATION

The present application claims the priority benefit under 35 U.S.C. §119(e) to U.S. Provisional Application No. 60/538,019, filed Jan. 20, 2004.

### FIELD OF THE INVENTION

The present invention relates generally to a semiconductor processing apparatus and more particularly, a vapor reactant source system for a semiconductor processing apparatus, such as for depositing thin films on a substrate surface.

### BACKGROUND OF THE INVENTION

Thin films may be grown on the surface of substrates by several different methods. These methods include vacuum evaporation deposition, Molecular Beam Epitaxy (MBE), different variants of chemical vapor deposition (CVD) including low-pressure and organometallic CVD and plasma-enhanced CVD, and atomic layer epitaxy (ALE), which has been more recently referred to as atomic layer deposition (ALD) for the deposition of a variety of materials.

Orifices are used as gas flow restrictors, for example in CVD processes. An orifice is placed in a gas flow conduit so that a pressure drop over the orifice is obtained. When gas is flowing through the orifice, the gas flow conduit upstream of the orifice has an absolute pressure P₁ and the downstream part of the gas flow conduit has an absolute pressure P₂. Gas velocity reaches sonic conditions when the downstream absolute pressure P_{2.} is not more than 52.8% of the upstream absolute pressure P₁, i.e., the absolute pressure ratio P₂/P₁ is not more than 0.528. Sonic conditions result in a gas flow in which the velocity of the gas becomes choked or limited. Such a flow condition is referred to as choked-flow or sonic flow. The velocity of the gas cannot be higher than the sonic velocity, so increasing the upstream absolute pressure P₁ and/or decreasing the downstream absolute pressure does not change the gas velocity as long as the ratio of P₂/P₁ does not rise above 0.528. However, increasing the upstream absolute pressure P₁ increases the density of the gas and the mass flow rate through the orifice will increase linearly with increasing upstream absolute pressure P₁ even though the velocity does not increase.

In ALD, the sequential introduction of precursor species (e.g., a first precursor and a second precursor) to a substrate located within a reaction chamber is generally employed. Typically, one of the initial steps of ALD is the chemisorption of the first precursor on the active sites of the substrate. Conditions are such that the process is self-terminating or saturative and no more than a monolayer of the first precursor is chemisorbed on the substrate.

For example, the first precursor can comprise ligands that remain on the chemisorbed species, and which prevent further chemisorption. Accordingly, deposition temperatures are maintained within so-called ‘ALD window’: above the precursor condensation temperatures and below the precursor thermal decomposition temperature. The initial step of chemisorption of the first precursor is typically followed by a first purging stage, where the excess first precursor and possible reaction by-products are removed from the reaction chamber.

The second precursor is then introduced into the reaction chamber. The first and second precursors typically react with each other. As such, the chemisorbed monolayer of the first precursor reacts instantly with the introduced second precursor thereby producing the desired thin film. This reaction terminates once the chemisorbed first precursor has been consumed. The excess of second precursor and possible reaction byproducts are then removed by a second purge stage. Thus each cycle produces no more than one molecular monolayer in a self-limited manner, although some variants of ALD attempt to increase the deposition above one monolayer per cycle. The cycle can be repeated to grow the film to a desired thickness. Cycles can also be more complex. For example, the cycles can include three or more reactant pulses separated by purge and/or evacuation steps.

ALD source systems for providing the precursors and controlling the purge steps have been rather expensive because of costly mass flow controllers (MFCs) that have been used for adjusting the flow rate of inert carrier gas to the precursor sources. In ALD systems rapid switching of gases is required, but MFCs often have problems due to rather long internal settling time and pressure fluctuations within source systems are induced. Such pressure fluctuations are undesirable for a number of reasons, including unwanted reactant interactions, condensation of reactants and particulate generation.

Thus, there is a need for an improved ALD source system and method for depositing thin layers that addresses the problems described above.

### SUMMARY OF THE INVENTION

According to one aspect of the present invention, an apparatus is provided for providing vapor phase reactants to an atomic layer deposition chamber. The apparatus preferably includes a choked-flow element with an on-off valve and pressure control along a gas flow path between a gas source and an atomic layer deposition chamber. In one embodiment the choked-flow element is an orifice adjacent the on-off valve. In another embodiment the choked-flow element is a capillary insert attached to the on-off valve. The choked-flow element is preferably located immediately upstream of the on-off valve, the on-off valve controlling pulsing to the chamber.

A method for growing a thin film on a substrate in a reaction chamber by an ALD process is also disclosed. A first reactant source and an inactive gas source are provided. The first reactant is fed from the first reactant source to the reaction chamber. The gaseous first reactant passes through a first choked-flow element and a gas flow control valve prior to entering the chamber. Inactive gas is fed to the reaction chamber from the inactive gas source. Preferably, the choked flow element is adjacent to the gas flow control valve.

In one embodiment the choked-flow element is an orifice. The orifice may be located upstream of the gas flow control valve. In another embodiment the choked-flow element is a capillary insert attached to the gas flow control valve. The first reactant source may be a solid, liquid or gas.

A source system for an atomic layer deposition reactor is also provided, comprising a first reactant source, an inert gas source, a first gas conduit connected to the first reactant source and a second gas conduit connected to the inert gas source. A first choked-flow element is disposed in the first gas conduit and a second choked-flow element is disposed in the second gas conduit. A reaction chamber is in fluid communication with the first and second gas conduits. The system also comprises a first gas flow control valve, which comprises a first gas inlet, a second gas inlet and a first gas outlet. The first gas inlet is in fluid communication with the first gas conduit and the second gas inlet is in fluid communication with the second gas conduit. The system may also comprise a pressure control device, for controlling the pressure of the first reactant. The system may further comprise additional reactant sources, each having a separate gas conduit and choked-flow element.

In another aspect the invention provides a gas flow controller comprising a reactant source, an inactive gas source and, a gas flow control valve in fluid communication with and upstream of the reactant source. A choked-flow element is preferably located upstream of the reactant source and a reaction chamber is located downstream of the gas control valve.

In a further aspect, the invention concerns a method of delivering reactants to a reaction chamber, such as in an atomic layer deposition process. One or more reactant sources are provided. Reactants are fed from the reactant sources through a gas flow conduit into the reaction chamber. A choked-flow condition is established upstream of the reaction chamber.

Further aspects, features and advantages of the present invention will become apparent from the following description of the preferred embodiments.

### BRIEF DESCRIPTION OF THE DRAWINGS

FIGS. 1-10 are non-limiting illustrations (not to scale) of a source system in accordance with various embodiments disclosed below.

FIGS. 1a-1d are schematic views of an ALD gas dosing system.

FIG. 2 illustrates a schematic view of an ALD system with three sources during a purge step.

FIG. 3 illustrates a schematic view of the ALD system during a pulse of reactant A.

FIG. 4 illustrates a schematic view of the ALD system during a pulse of reactant B.

FIG. 5 illustrates a schematic view of the ALD system during a pulse of reactant C.

FIG. 6 illustrates an ALD system with two sources having a balancing flow construction.

FIG. 7 illustrates an ALD system with two sources during a pulse of reactant X.

FIG. 8 illustrates an ALD system with two sources during a pulse of reactant Y.

FIG. 9 illustrates an ALD solid source system during a purge step.

FIG. 10 illustrates an ALD solid source system during a reactant pulse.

### DETAILED DESCRIPTION OF THE PREFERRED EMBODIMENT

The gas dosing systems and methods described herein are preferably used for atomic layer deposition (ALD) processes and are typically utilized in an ALD reactor. As a result, the gas dosing systems and methods presented herein are described in the context of atomic layer deposition (ALD) processes. However, one of skill in the art will recognize that they can be utilized in the provision of reactants in other deposition processes. In addition, while not separately illustrated, the skilled artisan will readily appreciate that the flow sequences described herein can be controlled by a computer through software programming and/or hardwiring arranged to open and close gas control valves in the desired sequence.

The gas dosing systems described herein typically comprise a reactant supply source, a gas flow control valve and at least one pre-calibrated orifice that acts as a choked-flow element. While described with the use of a pre-calibrated orifice, one of skill in the art will recognize that other elements that are able to produce a choked-flow may be substituted for the pre-calibrated orifice. The most basic system comprises a reactant supply source, a gas flow conduit, a gas control valve, preferably an on/off valve, and a choked-flow element, preferably a pre-calibrated orifice, placed in the gas flow conduit. The choked-flow element is preferably near the gas control valve. Because the gas conduit downstream of the valve seat of the gas flow valve has high gas flow conductance, by placing the choked-flow element upstream of the gas control valve, the gas flow can be switched on and off quickly. Thus, the choked-flow element is preferably upstream of the gas flow control valve. If the choked-flow element is provided downstream of the gas flow valve, there is a gas volume between the valve and the orifice and it takes some time to empty this volume after the valve is closed, thus increasing the amount of time it takes to switch the gas flow on and off. Nevertheless, in some circumstances the choked-flow element is located downstream of the gas control valve. For example, a capillary insert can be placed downstream near the valve seat. By placing the choked-flow element in close proximity to the valve, the gas volume that must be emptied after closing the valve is minimized. As explained below, a choked-flow element can also be provided either upstream or downstream of the valve controlling inert gas flow. With respect to the inert gas flow, the upstream or downstream position of the check-flow element with respect to the gas flow valve is less important as compared to the reactant flow because the inert gas volume between the inert gas and the flow valve is less likely to affect deposition in the reactor.

The pressure is preferably controlled such that the ratio of the pressure downstream of the orifice (P2) to the pressure upstream of the orifice (P1) is not more than 0.528, producing a choked-flow situation. In some situations, such as when a solid reactant source is utilized, the pressure ratio is preferably maintained by the use of a pressure controller. In other situations, such as when a liquid or gaseous reactant source is utilized, the pressure ratio is preferably maintained by controlling the temperature of the reactant source.

Typically the gas dosing system will also comprise an inert gas source. The inert gas source is preferably in fluid communication with a gas flow control valve. In some embodiments the gas flow control valve is a three way valve that can control the flow of both reactant and inert gas. In this case the gas flow control valve preferably comprises two gas inlets, one for reactant and one for inert gas. A separate choked-flow element is preferably located upstream of each gas inlet.

The mass flow rate through an orifice is a function of gas velocity, gas density and orifice area. Gas density to the upstream of the orifice is controlled by controlling the upstream pressure of the gas. The orifice area is selected and the orifice is pre-calibrated so that the orifice area is within the specifications necessary to produce a choked-flow situation. The gas velocity is forced to the sonic velocity by setting the absolute upstream pressure to a sufficiently high value so that the absolute pressure ratio P₂/P₁ will be within the range 0-0.528. There is now only one simple control parameter, upstream pressure, related to the dosing device consisting of a pre-calibrated orifice and a pulsing valve. The upstream pressure is set by a pressure regulator or controller that is preferably controlled with a computer through software programming. Because the pulsing valve is in fluid communication with a low-pressure reaction chamber, typically at about 0.5-10 mbar, the downstream pressure will not affect the gas velocity through the orifice as long as the absolute pressure ratio P₂/P₁ is within the range 0-0.528. As long as the upstream absolute pressure is kept constant, constant mass flow rate of the gas through the orifice and the pulsing valve is obtained.

When the pulsing valve is opened, the mass flow rate of the gas through the orifice will settle within milliseconds to a constant value. When the pulsing valve is closed, the mass flow rate of the gas through the orifice will drop within milliseconds to zero. Accurate dosing and fast pulsing of a gas is obtained with the dosing system.

According to one embodiment reactant vapor is injected to inactive gas stream within a three-way valve (e.g. PLT series, Hitachi Metals, Ltd.) that has two pre-calibrated orifices at the gas inlets. One orifice is placed to the upstream side of inactive gas conduit and one orifice is placed to the upstream side of the reactant vapor conduit. Examples of orifice constructions include VCR-orifice, separate orifice component and orifice insert that can be incorporated in a pulsing valve to reduce dead volume within a flow conduit. Orifices with ±0.5% NIST-calibration are commercially available.

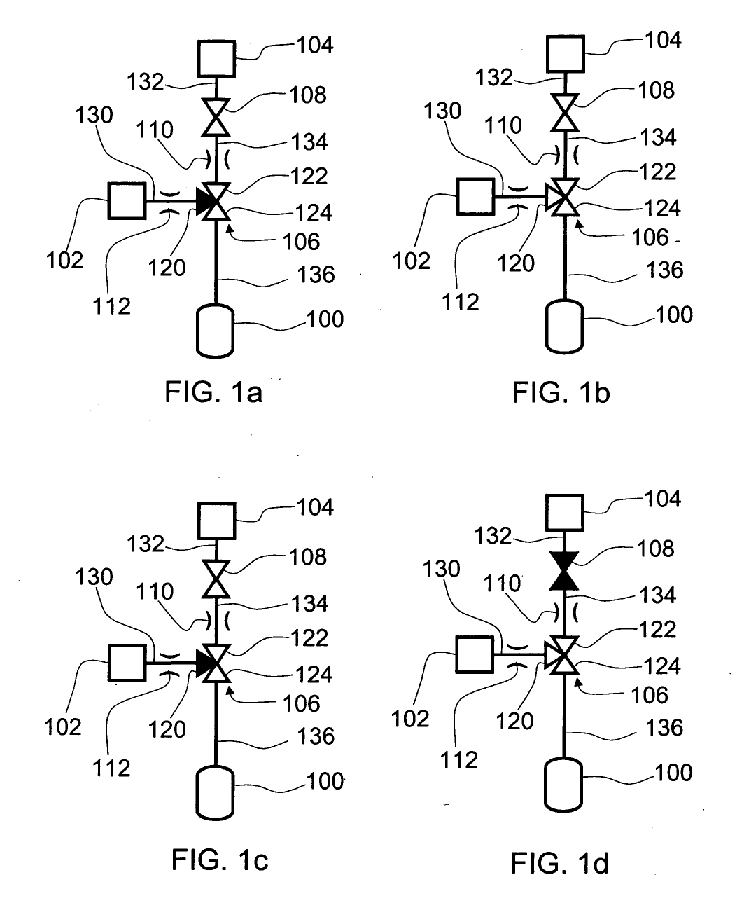

FIGS. 1a-1d illustrate a gas dosing system having a three-way valve constructed according to one embodiment of the invention. A reactant source 102 and an inactive or inert gas source 104 are in controlled fluid communication with a reaction space 100. The reactant source 102 contains gaseous, liquid or solid reactant. In the case of a gaseous reactant, such as ammonia (NH₃), the reactant vapor pressure is set to a selected value with a pressure regulator or controller (not shown). In the case of liquid and solid reactants, such as trimethyl aluminum ((CH₃)₃Al) and hafnium tetrachloride (HfCl₄), respectively, the pressure of the reactant vapor is controlled with the temperature of the reactant source 102. The pressure of the inactive gas source 104 is set to a desired value with a pressure controller (not shown).

A three-way valve 106, having a reactant inlet (source side) 120, inactive gas inlet 122 and a common gas outlet 124, controls the flow of gases into a reaction space 100. The reaction space 100 has an exhaust outlet that is preferably connected to a vacuum pump (not shown). There are two preferred methods of operating the three-way gas dosing system. In each case, however, the dosing system provides reactant during a “pulse” step and provides inactive gas to purge the reaction chamber during a “purge” step. According to the first dosing method inactive gas flows continuously through the three-way valve. According to the second dosing method the flow of inactive gas is stopped during a reactant pulse. The first dosing method is especially suitable for reactants that have relatively high vapor pressure, while the second dosing method is especially suitable for reactants that have relatively low vapor pressure.

The purging step of the first method is shown in FIG. 1a. The reactant inlet 120 of the three-way valve 106 is closed and the reactant source 102 is isolated from the reaction space 100. Inactive gas control valve 108, preferably an on/off valve, is kept open so that inactive gas flows from the inactive gas source 104 along the section of the conduit 132 through the inactive gas control valve 108, along the section of the conduit 134, through the pre-calibrated orifice 110, through the three-way valve 106, and along the in-feed conduit 136 into the reaction space 100.

The pulsing step of the first method is shown in FIG. 1b. Inactive gas flows from the inactive gas source 104 along the section of the conduit 132 through the inactive gas control valve 108, along the section of the conduit 134, through the pre-calibrated orifice 110, through the three-way valve 106, and along the in-feed conduit 136 into the reaction space 100. The reactant inlet 120 of the three-way valve 106 is opened. Reactant vapor flows from the reactant source 102 along the conduit 130, through the pre-calibrated orifice 112 into to the three-way valve 106 where the reactant vapor is injected into the inactive gas stream. The gas mixture flows from the common gas outlet 124 along the in-feed conduit 136 into the reaction space 100.

As mentioned above, the second dosing method is especially suitable for reactants that have relatively low vapor pressure. The purging step of the second method is depicted in FIG. 1c. The reactant inlet 120 of the three-way valve 106 is closed and the reactant source 102 is isolated from the reaction space 100. Inactive gas control valve 108, an on/off valve, is kept open so that inactive gas flows from the inactive gas source 104 along the section of the conduit 132 through the inactive gas control valve 108, along the section of the conduit 134, through the pre-calibrated orifice 110, through the three-way valve 106, and along the in-feed conduit 136 into the reaction space 100. Inactive gas pushes residual reactant vapor along the in-feed conduit 136 towards the reaction space 100 and thus purges the conduit and the reaction space.

The pulsing step of the second method is depicted in FIG. Id. The inactive gas control valve 108, preferably an on/off valve, is closed so that the inactive gas source 104 is isolated from the reaction space 100. As a result, gas pressure in the in-feed conduit 136 drops to a low level. The reactant inlet 120 of the three-way valve 106 is opened and reactant vapor flows from the reactant source 102 along the conduit 130, through the pre-calibrated orifice 112 into to the three-way valve 106. Reactant vapor continues to flow from the common gas outlet 124 along the in-feed conduit 136 into the reaction space 100. The flow of reactant vapor increases pressure inside the in-feed conduit 136.

Although not illustrated in FIGS. 1a-1d, it is also contemplated that a single pre-calibrated orifice can be placed downstream of the three-way valve 106.

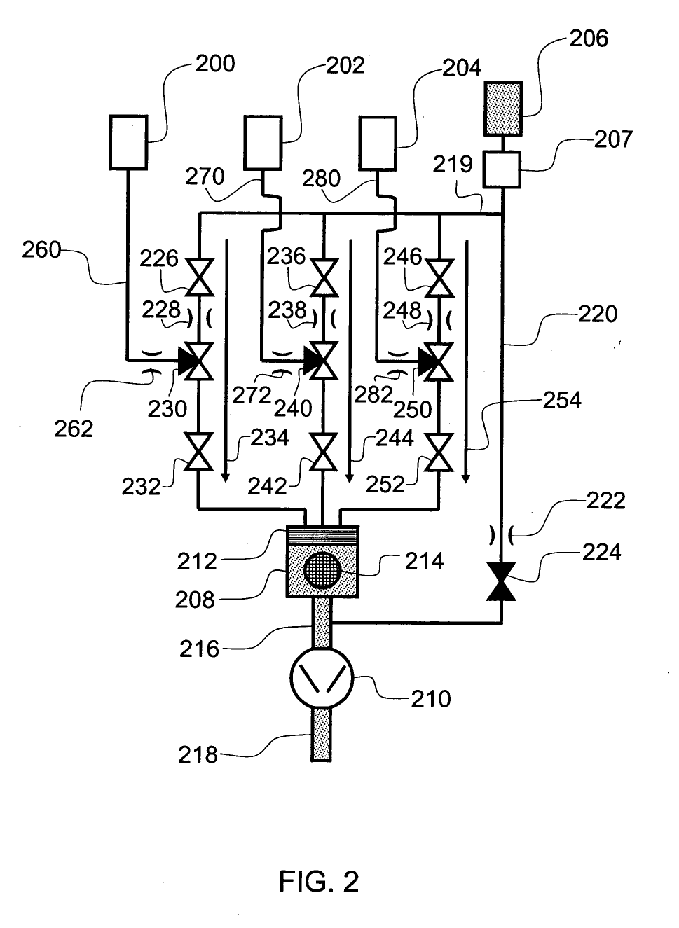

FIG. 2 illustrates a schematic view of an ALD system having source constructions according to an embodiment of the invention. The ALD system consists of three reactant supply sources 200, 202, 204, and an inactive gas supply source 206 coupled to an ALD reactor that has a gas mixing zone 212 and a reaction space 208, and a vacuum pump 210 connected with an exhaust line 216 to the reaction space 208. The vacuum pump is provided with an outlet 218 to expel compressed gases from the vacuum pump 210. A substrate or a wafer 214 is located within the reaction space 208. FIG. 2 illustrates the system configuration during a purging step.

In an exemplary case, the reactant supply sources 200, 202, 204 are reserved for reactants A, B and C, respectively. In this case reactant A is tungsten hexafluoride WF₆, reactant B is dry ammonia gas NH₃, and reactant C is triethyl boron TEB. These reactants are used for depositing a tungsten-nitride-carbide WNₓC_{y} thin film by ALD on a substrate 214. Each reactant supply source 200, 202, 204 is coupled through a source choked-flow element 262, 272, 282 to a three-way source pulsing valve 230, 240, 250. The gas lines are preferably heated from the gas mixing area 212 up to the source pulsing valves 230, 240, 250 to avoid condensation or physisorption of source chemicals to the inner surfaces of the gas lines.

In FIG. 2 by-pass isolation valve 224 is closed and inactive gas flow is directed only to a main purge line 219. The main purge line 219 is further divided into three local purge conduits. Each local purge conduit comprises an inactive gas flow control valve 226, 236, 246, a choked-flow element 228, 238, 248, a three-way source pulsing valve 230, 240, 250, and a reaction space isolation valve 232, 242, 252.

The choked-flow elements 228, 238, 248 of the local purge conduits cause a choked-flow condition, such that the speed of gas at the orifice or aperture of the choked-flow element is near the speed of sound, which is the maximum possible speed for the gas in this setup. The choked-flow elements are preferably pre-calibrated orifices of the same or substantially same size. The orifice is, for example, a metal foil or thin ceramic plate that has a hole with a selected diameter. The mass flow rate of the inactive gas through the choked-flow elements 228, 238, 248 is directly proportional to the pressure of the inactive gas in the upstream side of the choked-flow elements. Because the pressure of the inactive gas is set to a constant value by the pressure controller 207 and three choked-flow elements are of the substantially same size, the mass flow rate of the inactive gas through the three-way source pulsing valves 230, 240, 250 will be the same during each purge step.

During the purge step the source supply side of each three-way source pulsing valve is kept closed as indicated with a solid black triangle. Each reactant supply source 200, 202, 204 is isolated from the rest of the system and reactant molecules stay out of the reaction space 208 and the conduits between the reaction space and source pulsing valves. Inactive gas purges each source line to a direction indicated with an arrow 234, 244, 254 towards the gas mixing area 212 and through the reaction space 208 to the exhaust conduit 216.

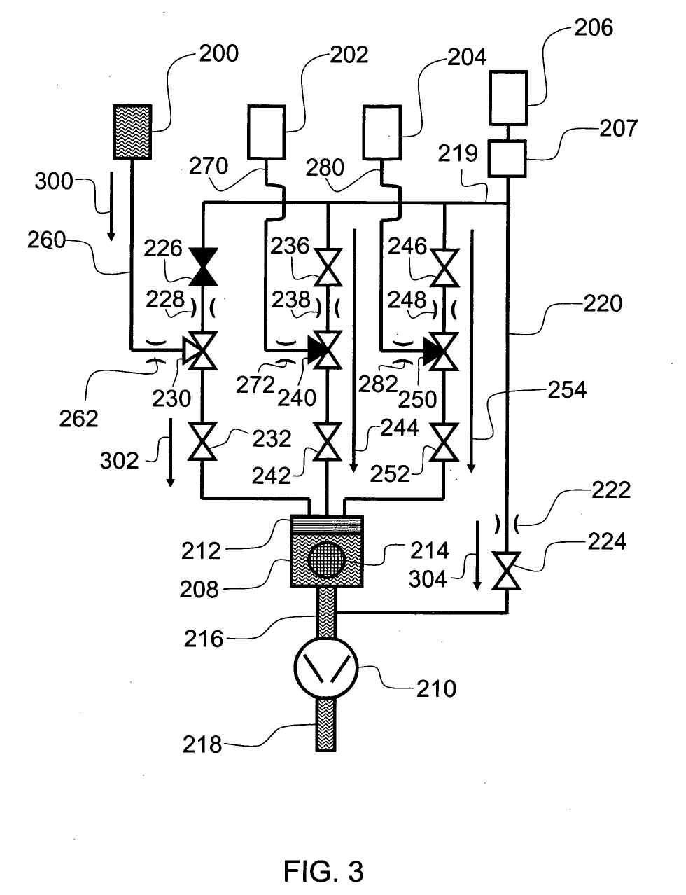

Turning to FIG. 3, a schematic view of the ALD system depicting a pulse step in which reactant from reactant supply source 200 is provided. Continuing the exemplary flow begun above, the reactant is WF₆. Inactive gas flow through the three-way source pulsing valve 230 is terminated by closing the inactive gas flow control valve 226. Because the choked-flow element 222 is substantially same size as the choked-flow element 228, the substantially same mass flow rate of inactive gas that was flowing through the three-way WF₆ source pulsing valve 230 before closing the inactive gas flow control valve 226 is now directed to the by-pass line 220 by opening the by-pass isolation valve 224. The mass flow rate of inactive gas from the inactive gas supply source 206 is thus kept substantially constant at all times and pressure fluctuations of the inactive gas in the upstream side of the choked-flow elements 238, 248 are avoided.

The WF₆ source side of the three-way valve 230 is opened as indicated with a white triangle. WF₆ vapor flows from the source 200 through the WF₆ source conduit 260 as indicated with an arrow 300, through the choked-flow element 262 and three-way valve 230, through the reaction space isolation valve 232 as indicated with an arrow 302, into the reaction space 208. WF₆ source 200 preferably comprises a pressure controller (not shown). A substrate 214 is exposed to WF₆ molecules that chemisorb on the substrate until available reactive surface sites have been consumed and the surface reaction self-terminates. After the WF₆ pulse step the WF₆ supply side of the three way valve 230 is closed, the inactive gas flow control valve 226 is opened, the by-pass isolation valve 224 is closed, and the system enters the purge step configuration illustrated in FIG. 2.

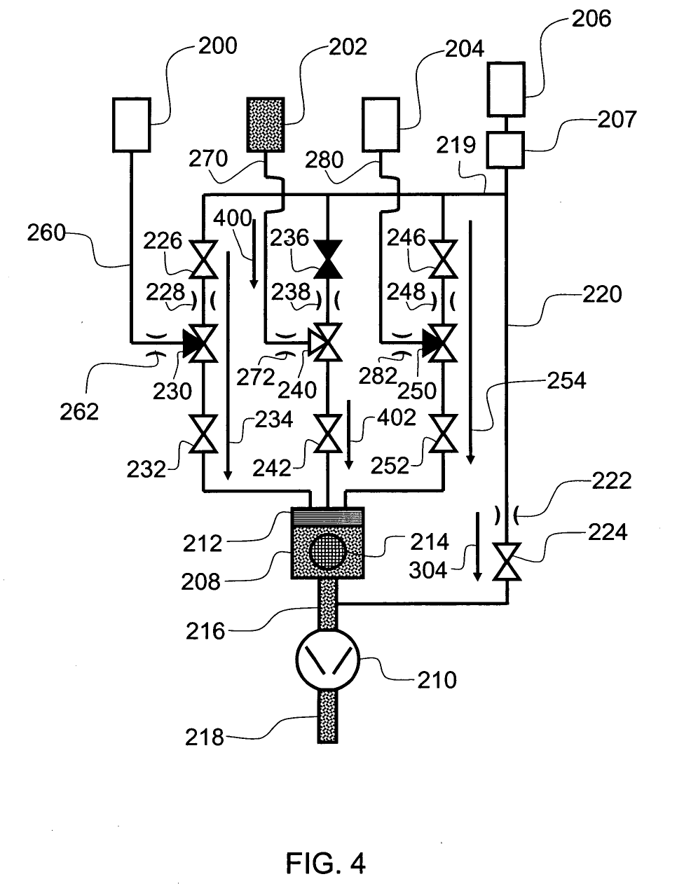

FIG. 4 illustrates a schematic view of the ALD system in which a pulse of reactant from reactant source 202 is provided, here an NH₃ pulse step. Inactive gas flow through the three-way NH₃ source pulsing valve 240 is terminated by closing the inactive gas flow control valve 236. The same mass flow rate of inactive gas that was flowing through the three-way NH₃ source pulsing valve 240 before closing the inactive gas flow control valve 236 is now directed to the by-pass line 220 by opening the by-pass isolation valve 224. The mass flow rate of inactive gas from the inactive gas source 206 is thus kept constant all the time and pressure fluctuations of the inactive gas in the upstream side of the choked-flow elements 228, 248 are avoided.

The NH₃ source side of the three-way valve 240 is opened as indicated with a white triangle. NH₃ vapor flows from the source 202 through the NH₃ source conduit 270 as indicated with an arrow 400, through the choked-flow element 272 and three-way valve 240, through the reaction space isolation valve 242 as indicated with an arrow 402, into the reaction space 208. NH₃ source 202 preferably comprises a pressure regulator (not shown). The substrate 214 is exposed to NH₃ molecules that chemisorb on the substrate until available reactive surface sites have been consumed and the surface reaction self-terminates. After the NH₃ pulse step the NH₃ source side of the three way valve 240 is closed, the inactive gas flow control valve 236 is opened, the by-pass isolation valve 224 is closed, and the system enters the purge step configuration shown in FIG. 2.

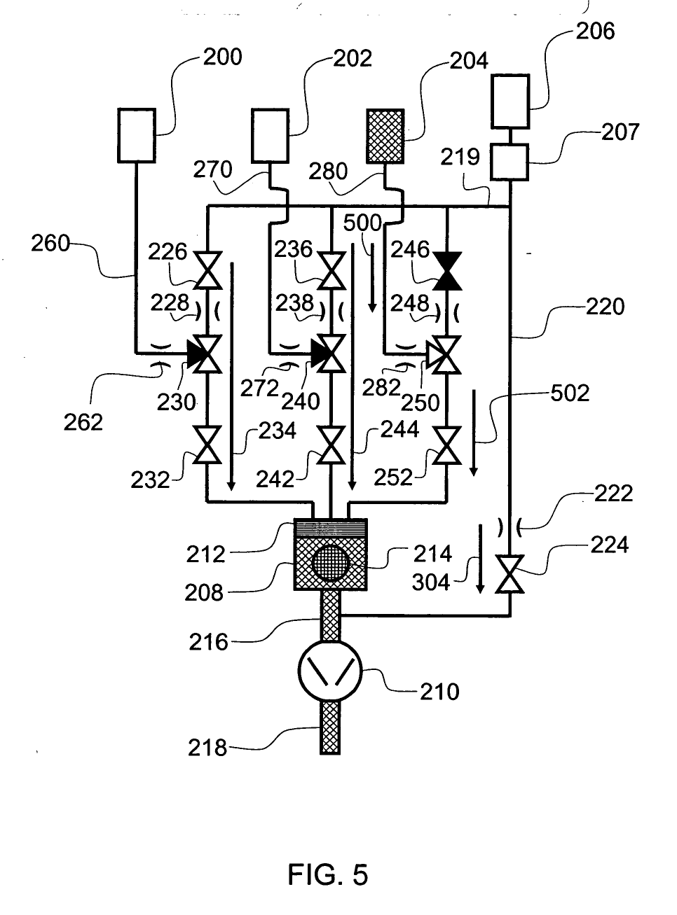

FIG. 5 illustrates a schematic view of the ALD system during provision of reactant from reactant source 204, here a TEB pulse step. Inactive gas flow through the three-way TEB source pulsing valve 250 is terminated by closing the inactive gas flow control valve 246. The same mass flow rate of inactive gas that was flowing through the three-way TEB source pulsing valve 250 before closing the inactive gas flow control valve 246 is now directed to the by-pass line 220 by opening the by-pass isolation valve 224. The mass flow rate of inactive gas from the inactive gas supply source 206 is thus kept constant all the time and pressure fluctuations of the inactive gas in the upstream side of the choked-flow elements 228, 238 are avoided.

The TEB source side of the three-way valve 250 is opened as indicated with a white triangle. TEB vapor flows from the source 204 through the TEB source conduit 280 as indicated with an arrow 500, through the choked-flow element 282 and the three-way valve 250, through the reaction space isolation valve 252 as indicated with an arrow 502, into the reaction space 208. TEB has lower vapor pressure than WF₆ or NH₃, so the TEB supply source 204 does not require a pressure regulator to achieve choked-flow conditions. The substrate 214 is exposed to TEB molecules that react with the substrate surface until available reactive surface sites have been consumed and the surface reaction self-terminates. At the end of the TEB pulse time the TEB source side of the three way valve 250 is closed, the inactive gas flow control valve 246 is opened, the by-pass isolation valve 224 is closed, and the system enters the purge step configuration shown in FIG. 2.

The inactive gas source 206 preferably contains inert or noble gas, by way of example, nitrogen or argon. The inactive gas is used to purge the reaction space and/or the gas flow conduits of excess reactant and reaction by-product gases. In case of low-vapor pressure reactants the inactive gas may be used to transport the reactant from the reactant source to the reaction space.

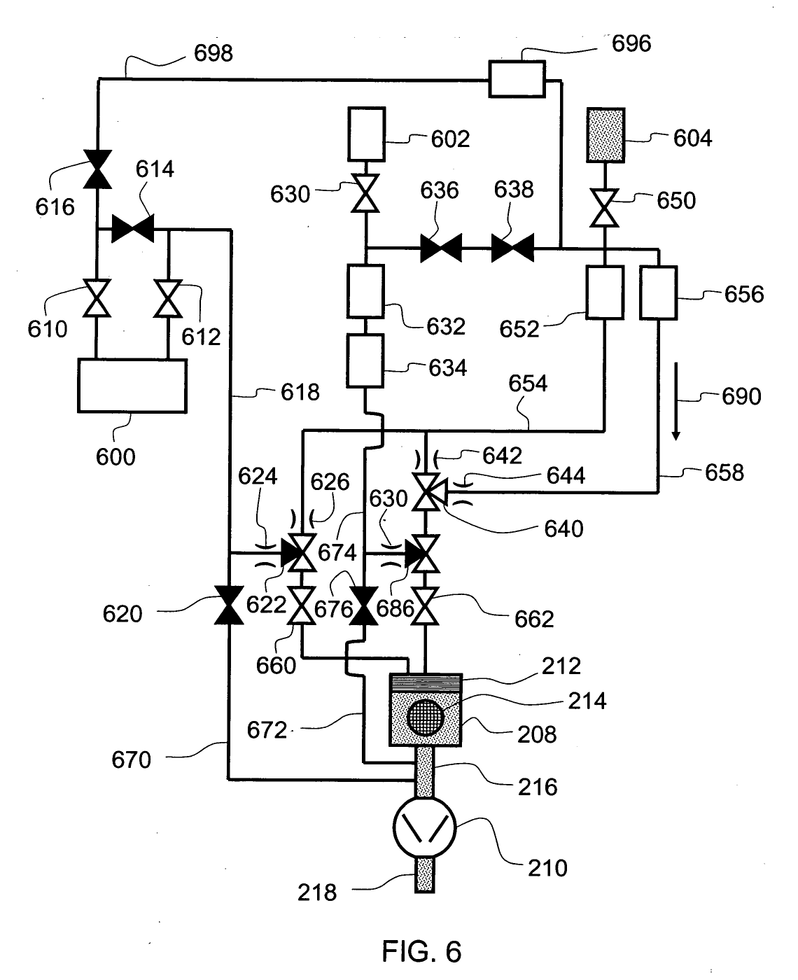

FIG. 6 illustrates a schematic view of an ALD source system that utilizes carrier gas and a balancing flow. In this exemplary case, reactant X is titanium tetrachloride TiCl₄, provided from reactant source 600 and reactant Y is dry ammonia NH₃, provided from reactant source 602. Inactive gas, for example nitrogen N₂, is provided from an inactive gas source 604 and it serves as a carrier and purge gas.

The TiCl₄ source 600 has an inlet valve 610, an outlet valve 612, a source by-pass valve 614 and a control valve for the carrier gas 616 for mixing with reactant vapor and for purging the TiCl₄ source conduit 618. The TiCl₄ supply source is in controlled fluid communication with the reaction space 208 through a three-way valve 622 that is used for pulsing TiCl₄ vapor into the reaction space. The TiCl₄ pulsing valve 622 has one choked-flow element 624 at the source inlet side and another choked-flow element 626 at the purge inlet side.

The NH₃ source 602 has a manual source isolation valve 630, a pressure regulator 632, an optional buffer volume 634, a manual line purge valve 636 and a computer-controlled line purge valve 638. The NH₃ source 602 is in controlled fluid communication with the reaction space 208 through a three-way valve 686 that is used for pulsing NH₃ vapor into the reaction space. The NH₃ pulsing valve 686 has a choked-flow element 680 at the source inlet side. The NH₃ source system is equipped with a balancing flow control that includes a three-way valve 640 for switching inactive gas flow. The inactive gas valve 640 has one choked-flow element 642 for restricting the primary inactive gas flow and another choked-flow element 644 for restricting the balancing flow of the inactive gas.

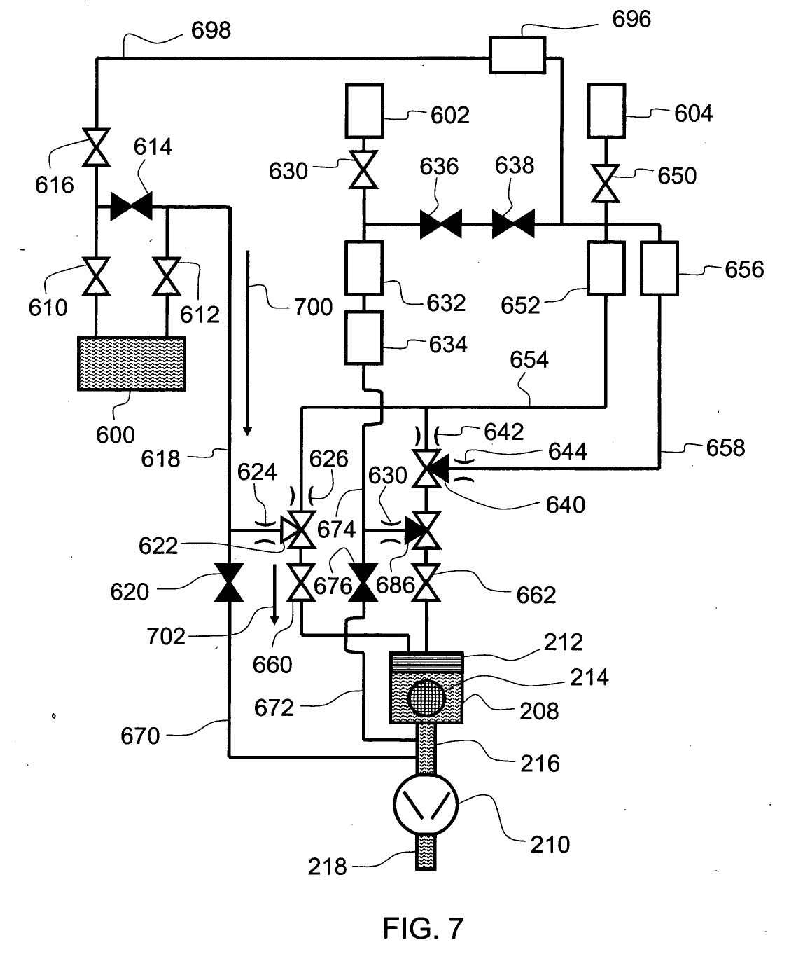

The inactive gas source 604 has a main isolation valve 650, a mass flow controller or a pressure controller 652 for letting inactive gas to the primary purge conduit 654, a pressure controller 656 for setting the gas pressure of the balancing flow conduit 658, and a pressure controller 696 for setting the gas pressure of the carrier gas conduit 698. A large fluctuation of mass flow in a reaction space may cause detrimental effects on deposition. Accordingly, it may be beneficial to maintain a substantially constant mass flow to the reaction space. In the illustrated embodiment, total mass flow in the reaction space may be kept constant if the mass flow 690 (see FIG. 6) of inactive gas is substantially the same as the mass flow 700 (see FIG. 7) of a gas misture consisting of inactive carrier gas and TiCl₄ vapor and the mass flow 800 of NH₃ gas. As will be explained below, the proper combination of pre-calibrated choked-flow elements and pressure settings can achieve this substantially same mass flow.

The reaction space 208 can be isolated from the gas in-feed conduits with the isolation valves 660, 662. Isolation is advantageous during the servicing of the chamber parts within the reactor. The reaction space is connected with an exhaust conduit 216 to a vacuum pump 210 that has an outlet 218 for expelling compressed gases from the vacuum pump. A by-pass conduit 670 is connected to the exhaust conduit 216 and it is used during the servicing of the TiCl₄ source 600 for draining any harmful gases such as air and TiCl₄ residues from the TiCl₄ source conduit 618. A similar by-pass conduit 672 is connected to the exhaust conduit 216 for removing any harmful gases from the NH₃ source conduit 674 through the by-pass isolation valve 676. The conduit 672 and the by-pass isolation valve 676 may be used during the servicing of the NH₃ source 602.

The configuration of the system during the purging step is shown in FIG. 6. The TiCl₄ supply source 600 is isolated from the reaction space 208 because the TiCl₄ source side of the pulsing valve 622 is closed as indicated with the solid black triangle. Inactive gas flows through the three-way TiCl₄ source pulsing valve 622 and its flow is restricted to a desired flow rate with the choked-flow element 626. The NH₃ supply source 602 is isolated from the reaction space 208 because the NH₃ source side of the pulsing valve 686 is closed as indicated with a black triangle. Inactive gas flows through the three-way balancing flow valve 640 and the three-way NH₃ source pulsing valve 686 and its flow is restricted to a desired flow rate with the choked-flow element 642. Because source chemicals are not flowing to the reaction space, the total gas flow rate to the reaction space would be smaller during the purge than during the pulse. The lower flow rate is compensated for with inactive gas by opening the balancing flow side of the three-way valve 640 as indicated with the white triangle. The choked-flow element 644 restricts the flow of the inactive gas (the balancing flow), indicated with an arrow 690, to the desired value. As a result, the total flow rate of gases into the reaction space 208 stays constant during the deposition process.

FIG. 7 illustrates the ALD source system during a pulse from reactant source 600, here TiCl₄. In the beginning of the TiCl₄ pulse time the gas flows are controlled as follows. The three-way balancing flow valve 640 is closed from the balancing flow side as indicated with a solid black triangle. The TiCl₄ source side of the three-way pulsing valve 622 is opened as indicated with a white triangle. The control valve for the carrier gas 616 is opened. Primary purge gas flows along the conduit 654. The flow is divided into two parts. One part of the primary purge flow goes through the choked-flow element 642, balancing flow valve 640, NH₃ source pulsing valve 686 and the reaction space isolation valve 662 to the gas mixing zone 212 and further into the reaction space 208. The other part of the primary purge flow goes through the choked-flow element 626, the TiCl₄ source pulsing valve 622 and the reaction space isolation valve 660 to the gas mixing zone 212 and further into the reaction space 208. Inactive carrier gas is injected into the TiCl₄ supply source 600 through the control valve for the carrier gas 616 and the inlet isolation valve 610. Gas mixture consisting of inactive carrier gas and TiCl₄ vapor exit the TiCl₄ supply source through the outlet isolation valve 612. The gas mixture is injected into the primary purge flow inside the TiCl₄ source pulsing valve 622 and it flows into the reaction space where the TiCl₄ molecules chemisorb on the surface of the substrate 214 until the reactive surface sites have been consumed and the chemisorption self-terminates.

At the end of the TiCl₄ pulse the gas flows system is configured as follows. The TiCl₄ source side of the three-way pulsing valve 622 and the control valve 616 for the carrier gas are closed and the TiCl₄ source 600 becomes isolated from the reaction space 208. The three-way balancing flow valve 640 is opened from the balancing flow side and inactive balancing gas flow is injected through the choked-flow element 644 into the primary purge gas flow inside the balancing flow valve 640. The primary purge gas flow pushes residual TiCl₄ vapor from the three-way TiCl₄ source pulsing valve 622 to the reaction space 208 and further to the exhaust conduit 216. The system is now in the purge step configuration shown in FIG. 6.

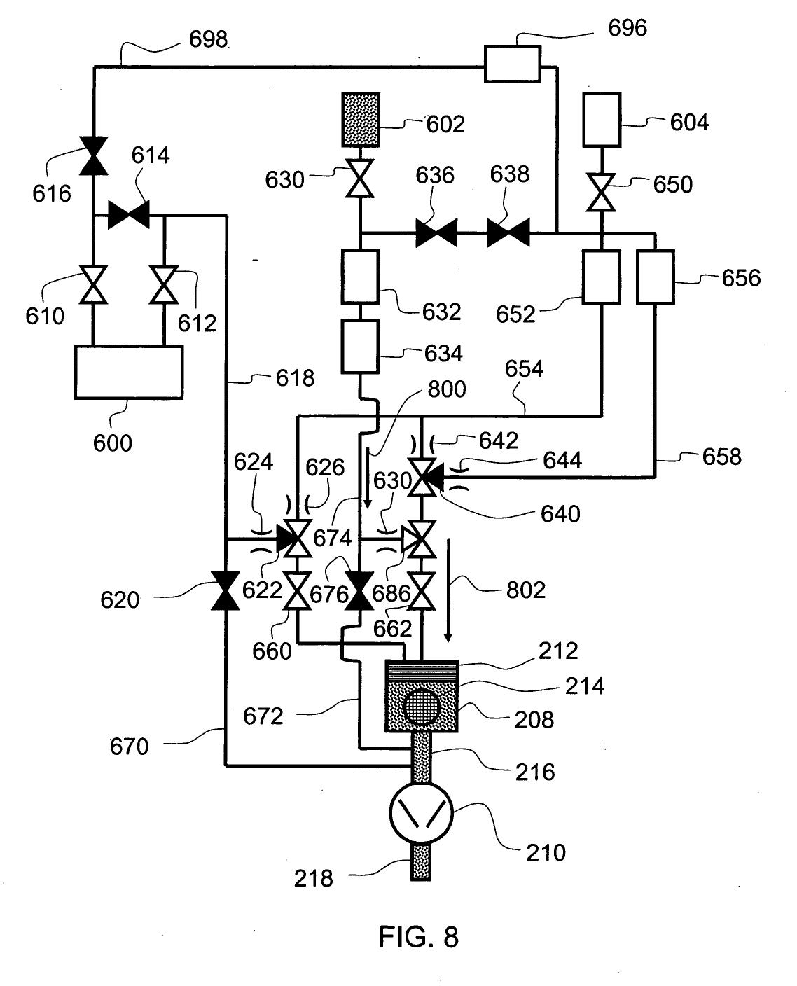

FIG. 8 illustrates the configuration of the ALD source system during an NH₃ pulse from reactant source 602. At the beginning of the NH₃ pulse the gas flows are configured as follows. The three-way balancing flow valve 640 is closed from the balancing flow side as indicated with solid black triangle. The NH₃ source side of the three-way pulsing valve 686 is opened as indicated with a white triangle. The primary purge gas flows along the conduit 654. The flow is divided into two parts. One part of the primary purge flow goes through the choked-flow element 642, balancing flow valve 640, NH₃ source pulsing valve 686 and the reaction space isolation valve 662 to the gas mixing zone 212 and further into the reaction space 208. The other part of the primary purge flow goes through the choked-flow element 626, the TiCl₄ source pulsing valve 622 and the reaction space isolation valve 660 to the gas mixing zone 212 and further into the reaction space 208. The NH₃ gas flows through the pressure regulator 632 and an optional buffering volume 634 and it is injected into the primary purge gas flow inside the three-way NH₃ source pulsing valve 686. The gas mixture consisting of inactive gas and NH₃ vapor flows through the reaction space isolation valve 662 to the gas mixing zone 212, as indicated with an arrow 802, and further into the reaction space 208 where the NH₃ molecules chemisorb on the surface of the substrate 214 until the reactive surface sites have been consumed and the chemisorption self-terminates.

At the end of the NH₃ pulse time the gas flow system is configured as follows. The NH₃ source side of the three-way pulsing valve 686 is closed and the NH₃ supply source 602 becomes isolated from the reaction space 208. The three-way balancing flow valve 640 is opened from the balancing flow side and inactive balancing gas flow is injected through the choked-flow element 644 into the primary purge gas flow inside the balancing flow valve 640. The primary purge gas flow pushes residual NH₃ vapor from the three-way NH₃ source pulsing valve 686 to the reaction space 208 and further to the exhaust conduit 216. The system is now in the purge step configuration shown in FIG. 6. The combination of a pre-calibrated choked-flow element and a pulsing valve enables fast and repeatable switching of gas flows.

Each ALD pulsing cycle comprising TiCl₄ pulse, purge, NH₃ pulse and purge steps leaves no more than a molecular layer of TiN on the surface of the substrate. TiN typically grows about 0.2 Å/pulsing cycle, which is clearly less than a molecular monolayer of TiN due to limited number of reactive surface sites and the steric hindrance resulting from the size of source chemical molecules. The pulsing cycle is repeated until a titanium nitride TiN film of the desired thickness is obtained.

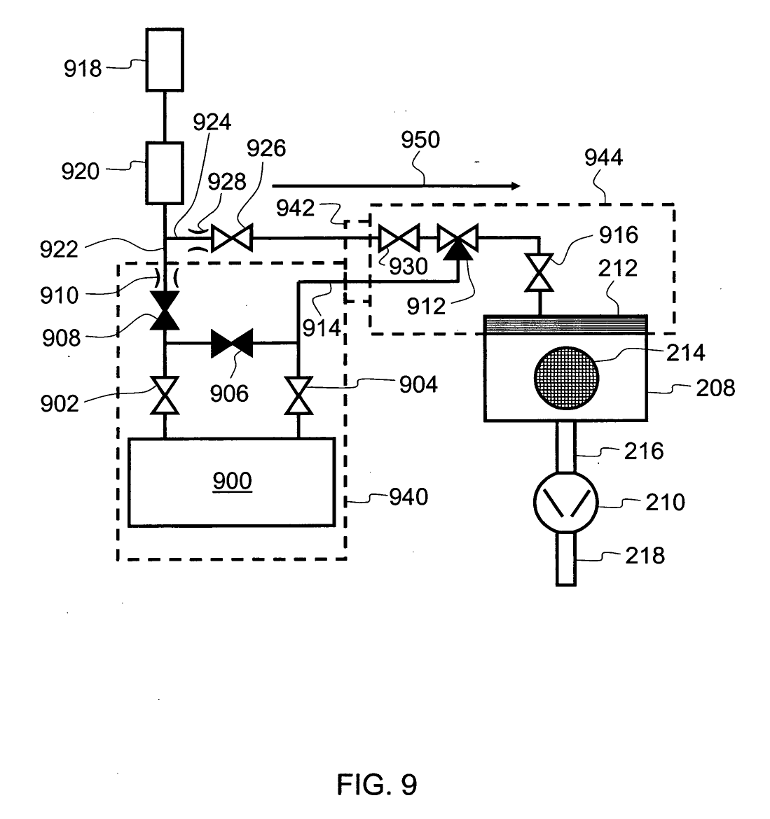

FIG. 9 illustrates an ALD solid source system constructed according to a further embodiment of the invention. The said system is illustrated in a purge step configuration. The solid source can be combined, for example, with at least one liquid or gas supply source to facilitate thin film deposition by ALD. In this exemplar case, hafnium tetrachloride HfCl₄ is used as a reactant and it is placed in the solid source 900. The said source 900 has an inlet isolation valve 902, an outlet isolation valve 904, a source by-pass valve 906 and a control valve 908 for the carrier gas for introducing inactive carrier gas into the source 900, and for purging the HfCl₄ source conduit 914 through the source by-pass valve 906 in case servicing of the source is needed. The HfCl₄ source is in controlled fluid communication with the reaction space 208 through a three-way HfCl₄ source pulsing valve 912 that is used for pulsing HfCl₄ vapor into the reaction space. The HfCl₄ source 900 has one choked-flow element 910 at the source inlet side. Another choked-flow element 928 is placed to the primary purge conduit 924 in front of the purge isolation valve 926. Inactive gas, for example nitrogen N₂, is provided from an inactive gas source 918 that has a pressure regulator or controller 920. Inactive gas serves as a carrier and purge gas for the deposition process. The HfCl₄ source 900 is inside a heated source zone 940. Source pulsing valve 912 with related conduits is inside the heated top plate zone 944 and connecting tubing between the reactant source and the reactor is inside the heated gas transport zone 942.

During the purge step the carrier gas control valve 908 and the source side of the three-way pulsing valve 912 are closed, as indicated with solid black triangles, and the HfCl₄ source 900 is isolated from the reaction space 208. The primary purge control valve 926 and optional heated zone isolation valve 930 are opened and inactive gas flows from the inactive gas source 918 through the pressure regulator 920, choked-flow element 928, primary purge control valve 926, optional heated zone isolation valve 930, three-way pulsing valve 912 and reaction space isolation valve 916 to the gas mixing zone 212 and further into the reaction space 208.

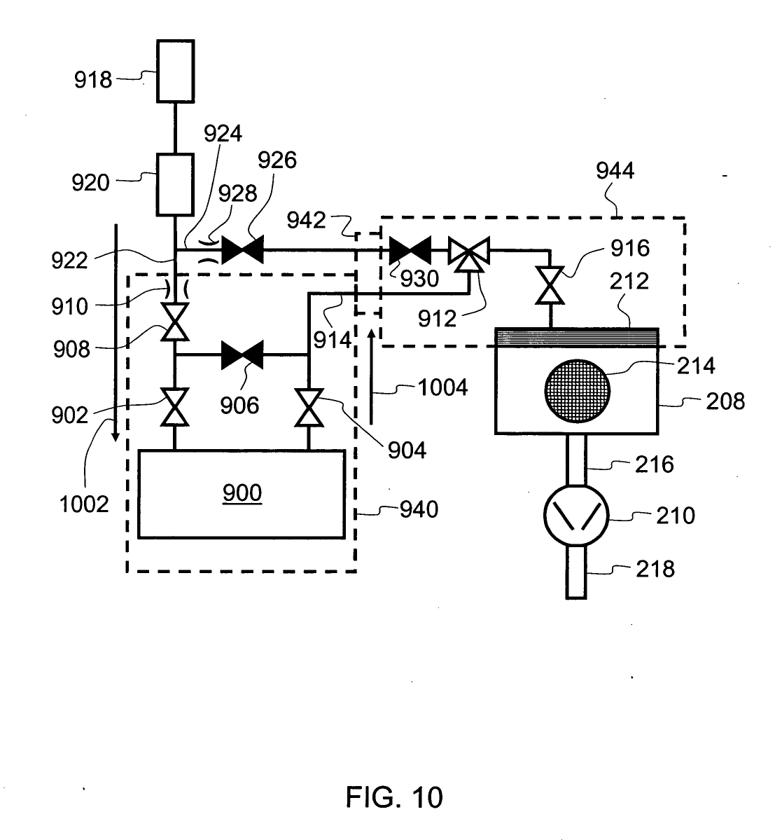

FIG. 10 illustrates the ALD solid source system being configured for a reactant pulse step. In the beginning of the HfCl₄ pulse the gas flows are controlled as follows. Solid source side of the three-way pulsing valve 912 is opened as indicated with a white triangle. The primary purge control valve 926 and optional heated zone isolation valve 930 are closed as indicated with solid black triangles. The carrier gas control valve 908 is opened. Inactive gas flows from the inactive gas source 918 through the pressure regulator 920, the choked-flow element 910, the carrier gas control valve 908 and the inlet isolation valve 902 into the HfCl₄ source where the inactive carrier gas blends with HfCl₄ vapor. The gas blending exits the solid source 900 through the outlet isolation valve 904 and it is dosed through the three-way HfCl₄ pulsing valve 912 to the reaction space 208 where the HfCl₄ molecules chemisorb on the surface of the substrate 214 until reactive surface sites have been consumed and the chemisorption self-terminates.

At the end of the HfCl₄ pulse time the gas flows are controlled as follows. The carrier control valve 908 is closed, primary purge control valve 926 and optional heated zone isolation valve 930 are opened and the solid source side of the three-way pulsing valve 912 is closed. The primary purge gas flow arriving along the conduit 924 pushes residual HfCl₄ vapor from the three-way solid source pulsing valve 912 to the reaction space 208 and further to the exhaust conduit 216. The system is now in the purge step configuration shown in FIG. 9.

Although not shown in FIGS. 9-10, the solid source system can be complemented for example with a liquid water source. Such a construction is used for the deposition of metal oxides, in one embodiment for the ALD growth of hafnium dioxide HfO₂. According to another embodiment the solid source system filled with a suitable metal source chemical is complemented with an ozone gas source for the deposition of metal oxides such as copper oxide CuO, or with an ammonia NH₃ gas source for the deposition of metal nitrides such as tantalum nitride TaN.

In this exemplar solid source case HfCl₄ is used as a solid metal source chemical. Generally, the illustrated solid source system can be used for solid reactants that can be heated to a source temperature of about 50-300° C. and have a vapor pressure of approximately 0.1-50 mbar at the source temperature. Examples of suitable solid reactants include zirconium compounds such as ZrCl₄, tantalum compounds such as TaF₅, aluminum compounds such as aluminum tri-isopropoxide Al(OPrⁱ)₃ and copper compounds such as bis-acetylacetonato copper Cu(acac)₂.

The construction of the ALD source system and the method of operating the ALD source system as presented hereinbefore produce certain benefits. Less expensive components are needed for the source system. Deposition process control is more precise and repeatability between depositions improves.

While the invention has been described with reference to preferred embodiments, it will be understood by those skilled in the art that various changes may be made and equivalents may be substituted for elements thereof without departing from the scope of the invention. In addition, many modifications may be made to adapt to a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

1. An apparatus, including a choked-flow element with an on-off valve and pressure control along a gas flow path between a gas source and an atomic layer deposition chamber.

2. The apparatus of claim 1, wherein the choked-flow element is an orifice adjacent the on-off valve.

3. The apparatus of claim 1, wherein the choked-flow element is a capillary insert attached to the on-off valve.

4. The apparatus of claim 1, wherein the choked-flow element is immediately upstream of the on-off valve, the on-off valve controlling pulsing to the chamber.

5. A method for growing a thin film on a substrate in a reaction chamber by an ALD process comprising:
providing a first reactant source;
providing an inactive gas source;
feeding gaseous first reactant from the first reactant source to the reaction chamber, wherein the first reactant passes through a first choked-flow element and a gas flow control valve prior to entering the reaction chamber; and
feeding inactive gas from the inactive gas source to the reaction chamber.

6. The method of claim 5, wherein the choked-flow element is adjacent to the gas flow control valve.

7. The method of claim 5, wherein the pressure of the first reactant is controlled by a pressure controller.

8. The method of claim 5, wherein the pressure of the first reactant is controlled by controlling the temperature of the first reactant source.

9. The method of claim 5, wherein the first reactant passes through the first choked-flow element prior to passing through the gas flow control valve.

10. The method of claim 5, wherein the inactive gas passes through a second choked-flow element.

11. The method of claim 5, wherein the first reactant and inactive gas pass through the same gas flow control valve.

12. The method of claim 11, wherein the first reactant and inactive gas pass through the same gas flow control valve simultaneously.

13. The method of claim 11, wherein the first reactant and inactive gas pass through the gas flow control valve alternately.

14. The method of claim 5, wherein the first choked-flow element is pre-calibrated.

15. The method of claim 14, wherein the first choked-flow element is an orifice.

16. The method of claim 15, wherein the orifice is located upstream of the gas flow control valve.

17. The method of claim 14, wherein the choked-flow element is a capillary insert attached to the gas flow control valve.

18. The method of claim 15, wherein the capillary insert is attached to an upstream side of the gas flow control valve.

19. The source system of claim 5, wherein the first reactant source is a solid, liquid or gas.

20. A source system for an atomic layer deposition reactor comprising:
a first reactant source;
an inert gas source;
a first gas conduit connected to the first reactant source;
a first choked-flow element disposed in the first gas conduit;
a second gas conduit connected to the inert gas source;
a second choked-flow element disposed in the second gas conduit;
a first gas flow control valve comprising a first gas inlet, a second gas inlet and a first gas outlet; and
a reaction chamber in fluid communication with the first and second gas conduits, wherein the first gas inlet is in fluid communication with the first gas conduit and the second gas inlet is in fluid communication with the second gas conduit, and the first gas outlet is in fluid communication with the reaction chamber.

21. The source system of claim 20, additionally comprising a pressure control device for controlling the pressure of the first reactant.

22. The source system of claim 21, wherein the pressure control device is located upstream of the first choked-flow element.

23. The source system of claim 20, wherein the first choked-flow element is located upstream of the first gas control valve.

24. The source system of claim 20, wherein the first choked-flow element is a pre-calibrated orifice.

25. The source system of claim 20, wherein the first choked-flow element is a capillary insert attached to the first gas inlet.

26. The source system of claim 20, additionally comprising:
a second reactant source;
a third gas conduit connected to the second reactant source;
a third choked-flow element disposed in the third gas conduit;
a second gas flow control valve comprising a third gas inlet and a fourth gas inlet, wherein the third gas inlet is in fluid communication with the second gas conduit and the fourth gas inlet is in fluid communication with the third gas conduit.

27. A gas flow controller comprising:
a reactant source;
an inactive gas source;
a gas flow control valve in fluid communication with and upstream of the reactant source;
a choked-flow element upstream of the gas flow control valve; and
a reaction chamber downstream of the gas flow control valve.

28. The gas flow controller of claim 27, wherein the reactant source is a solid source.

29. The gas flow controller of claim 27, wherein the choked-flow element is an orifice.

30. The gas flow controller of claim 27, wherein the choked-flow element is located upstream of the gas control valve.

31. The gas flow controller of claim 27, additionally comprising a pressure regulator in fluid communication with the reactant source.

32. The gas flow controller of claim 31, wherein the pressure regulator is located upstream of the choked-flow element.

33. A method of delivering reactants to a reaction chamber in an atomic layer deposition process comprising:
providing one or more reactant sources;
providing at least one gas flow conduit in fluid communication with the reaction chamber; and
feeding the reactants from the reactant sources through the at least one gas flow conduit into the reaction chamber, wherein a choked-flow condition is established upstream of the reaction chamber.
